(19) United States
(12) Patent Application Publication
(10) Pub. No.: US 2026/0282590 A1
(43) Pub. Date: Sep. 17, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Jia Liu, Yokohama Kanagawa (JP); Eitaro Miyake, Tachikawa Tokyo (JP)

(21) Appl. No.: 19/359,397

(22) Filed: Oct. 15, 2025

(30) Foreign Application Priority Data
Mar. 17, 2025 (JP) 2025 042762

(51) Int. Cl. H10F 55/255; H01L 25/16; H03K 17/785; H10F 55/00; H10F 77/00; H10F 77/50; H10F 77/60

(52) U.S. Cl. CPC H10F 55/255; H03K 17/785; H10F 55/18; H10F 77/50; H10F 77/60; H10F 77/933; H10W 90/00

(57) ABSTRACT

According to one embodiment, a semiconductor device includes: a substrate; a first transistor and a second transistor provided in the substrate; a first wiring provided in the substrate and contacting each of a source electrode of the first transistor and a source electrode of the second transistor; and a photocoupler provided on an upper surface of the substrate and configured to control states of the first transistor and the second transistor.

### CROSS-REFERENCE TO RELATED APPLICATIONS

This application is based upon and claims the benefit of priority from Japanese Patent Application No. 2025-042762, filed Mar. 17, 2025, the entire contents of which are incorporated herein by reference.

### FIELD

Embodiments described herein relate generally to a semiconductor device.

### BACKGROUND

There is known a photo relay device including two MOSFETs (Metal-Oxide-Semiconductor Field Effect Transistors) and a photocoupler. The photo relay device is a contactless relay, and is used to transmit an AC signal or a DC signal.

### BRIEF DESCRIPTION OF THE DRAWINGS

FIG. 1 is a circuit diagram showing an example of a circuit configuration of a semiconductor device according to a first embodiment.

FIG. 2 is a perspective view showing an example of a structure of the semiconductor device according to the first embodiment.

FIG. 3 is a plan view showing an example of a planar layout of an upper surface of the semiconductor device according to the first embodiment.

FIG. 4 is a plan view showing an example of a planar layout of a lower surface of the semiconductor device according to the first embodiment.

FIG. 5 is a sectional view taken along a line V-V in FIGS. 3 and 4 and showing an example of a sectional structure of the semiconductor device according to the first embodiment.

FIG. 6 is a sectional view showing an example of a sectional structure of the semiconductor device according to a modification of the first embodiment.

FIG. 7 is a plan view showing an example of a planar layout of an upper surface of a semiconductor device according to a second embodiment.

FIG. 8 is a plan view showing an example of a planar layout of a lower surface of the semiconductor device according to the second embodiment.

FIG. 9 is a sectional view taken along a line IX - IX in FIGS. 7 and 8 and showing an example of a sectional structure of the semiconductor device according to the second embodiment.

FIG. 10 is a sectional view showing an example of a sectional structure of a semiconductor device according to a first modification of the second embodiment.

FIG. 11 is a plan view showing an example of a planar layout of an upper surface of a semiconductor device according to a second modification of the second embodiment.

FIG. 12 is a plan view showing an example of a planar layout of an upper surface of a semiconductor device according to a third modification of the second embodiment.

FIG. 13 is a plan view showing an example of a planar layout of an upper surface of a semiconductor device according to a fourth modification of the second embodiment.

### DETAILED DESCRIPTION

In general, according to one embodiment, a semiconductor device includes: a substrate; a first transistor and a second transistor provided in the substrate; a first wiring provided in the substrate and contacting each of a source electrode of the first transistor and a source electrode of the second transistor; and a photocoupler provided on an upper surface of the substrate and configured to control states of the first transistor and the second transistor.

Embodiments will be described below with reference to the accompanying drawings. Note that in the following description, the same reference numerals denote components having the same functions and configurations. Dimensions and ratios in the drawings do not necessarily match the actuality.

A semiconductor device according to each embodiment is, for example, an SMD (Surface Mounted Device) electronic component. The semiconductor device according to the embodiment is, for example, a photo relay device configured to transmit an AC signal or DC signal of a large current. The semiconductor device according to the embodiment is applied to, for example, an industrial machine, a power conversion device, in-vehicle device, a home electrical appliance, a communication device, and the like. Note that each of the AC signal and the DC signal will also simply be referred to as a signal hereinafter.

### 1. First Embodiment

A semiconductor device according to a first embodiment will be described.

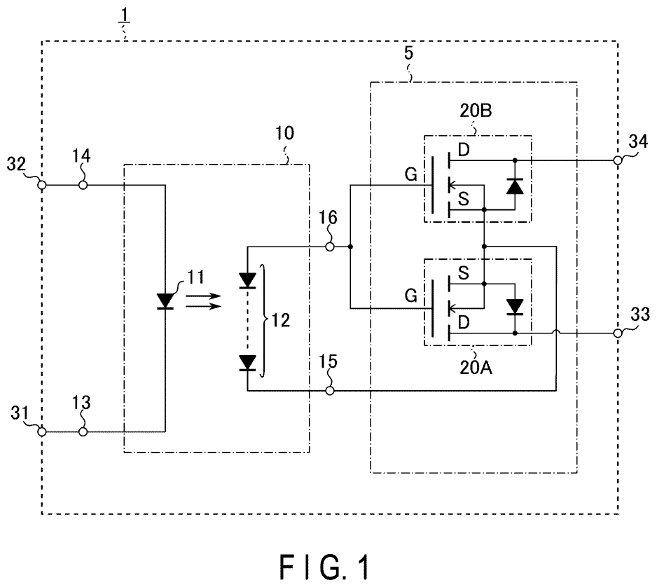

FIG. 1 is a circuit diagram showing an example of a circuit configuration of a semiconductor device according to a first embodiment.

A semiconductor device 1 includes electrodes 31, 32, 33, and 34. The electrodes 31 and 32 are pad electrodes implemented at the outer edge of a package, and are externally supplied with a voltage for driving the semiconductor device 1. While the semiconductor device 1 is driven, the semiconductor device 1 can transmit a signal via the electrodes 33 and 34.

The semiconductor device 1 includes a substrate 5 and a photocoupler 10. The substrate 5 is a component incorporating substrate incorporating MOSFETs (Metal-Oxide-Semiconductor Field Effect Transistors) 20A and 20B. The MOSFETs 20A and 20B are, for example, enhancement n-channel MOSFETs. The photocoupler 10 is a package incorporating a light-emitting element 11 and a light-receiving element 12. The photocoupler 10 includes terminals 13, 14, 15, and 16 as connection terminals to the outside.

The light-emitting element 11 is, for example, an LED (Light Emitting Diode). The cathode electrode of the light-emitting element 11 is connected to the electrode 31 via the terminal 13. The anode electrode of the light-emitting element 11 is connected to the electrode 32 via the terminal 14. The light-emitting element 11 is driven by power supplied to the electrodes 31 and 32. By the power supply via the electrodes 31 and 32, the light emission state of the light-emitting element 11 is switched between an ON state (turn-on state) and an OFF state (turn-off state).

The light-receiving element 12 is, for example, a PDA (Photo Diode Array). The light-receiving element 12 includes, for example, several to several ten photodiodes connected in series. The light-receiving element 12 may be a phototransistor. The cathode electrode of the light-receiving element 12 is connected to the terminal 15. The anode electrode of the light-receiving element 12 is connected to the terminal 16.

The source of the MOSFET 20A and the source of the MOSFET 20B are connected to the cathode electrode of the light-receiving element 12 via the terminal 15. The gate of the MOSFET 20A and the gate of the MOSFET 20B are connected to the anode electrode of the light-receiving element 12 via the terminal 16. The drain of the MOSFET 20A is connected to the electrode 33. The drain of the MOSFET 20B is connected to the electrode 34.

In the above-described circuit configuration of the semiconductor device 1, when the state of the light-emitting element 11 is changed from the OFF state to the ON state, the light-emitting element 11 emits light. The light-receiving element 12 changes the MOSFETs 20A and 20B from the OFF state to the ON state using a voltage generated by the photovoltaic effect caused by the light from the light-emitting element 11. Thus, the electrodes 33 and 34 are electrically connected. The semiconductor device 1 transmits a signal supplied to the electrode of one of the electrodes 33 and 34 to the electrode of the other of the electrodes 33 and 34 via the MOSFETs 20A and 20B.

When the state of the light-emitting element 11 is changed from the ON state to the OFF state, emission of light from the light-emitting element 11 is stopped. This changes the MOSFETs 20A and 20B from the ON state to the OFF state. In this way, the semiconductor device 1 electrically insulates the electrodes 33 and 34.

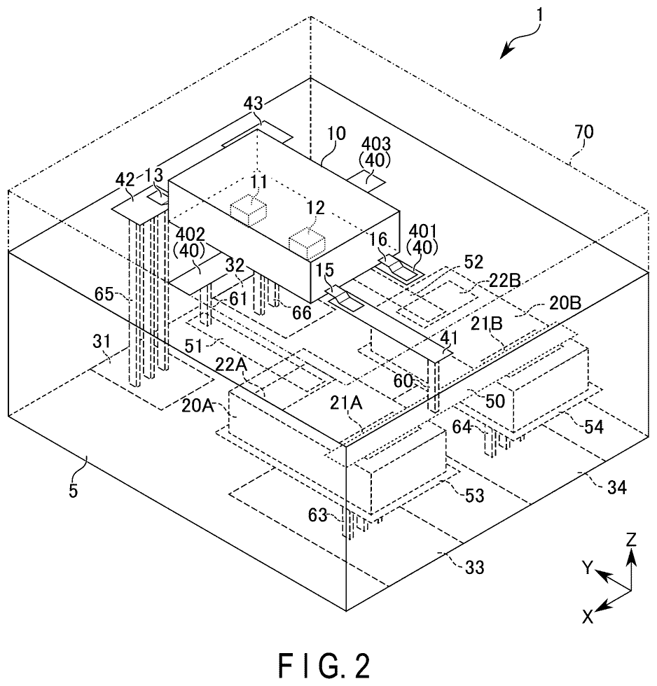

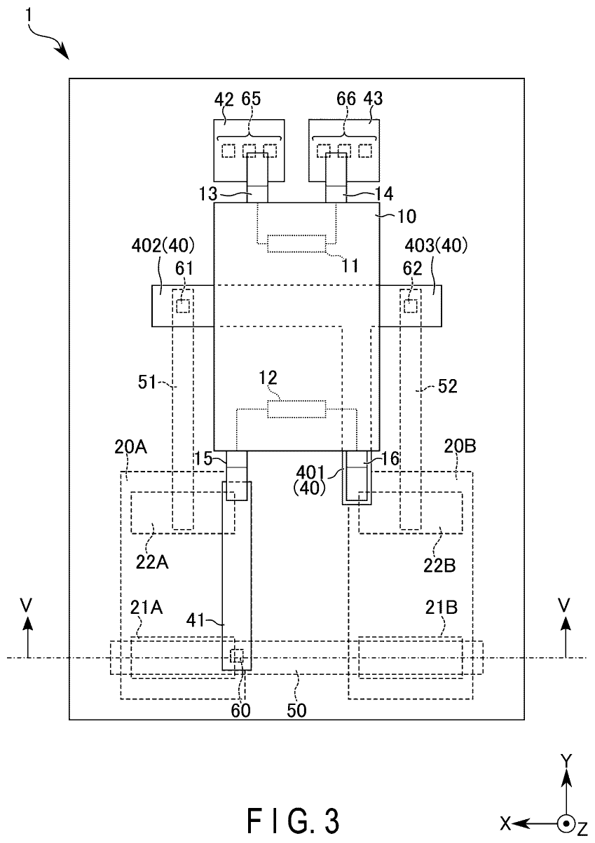

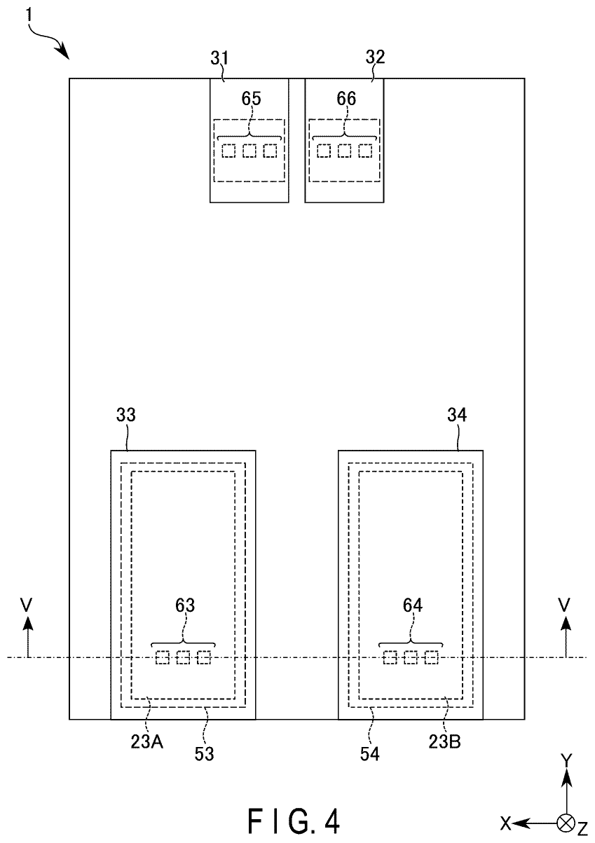

The structure of the semiconductor device 1 will be described next with reference to FIGS. 2, 3, and 4. FIG. 2 is a perspective view showing an example of the structure of the semiconductor device according to the first embodiment. FIG. 3 is a plan view showing an example of the planar layout of the upper surface of the semiconductor device according to the first embodiment. FIG. 4 is a plan view showing an example of the planar layout of the lower surface of the semiconductor device according to the first embodiment.

In the following description, the X-Y plane is a plane parallel to the mounting surface of the photocoupler 10 on the substrate 5. The X direction is a direction in which the MOSFETs 20A and 20B are arranged within the X-Y plane. The Y direction is a direction orthogonal to the X direction within the X-Y plane. The Z direction is a direction orthogonal to the X-Y plane. In the Z direction, a direction from the substrate 5 to the photocoupler 10 is called an upward direction and a direction from the photocoupler 10 to the substrate 5 is called a downward direction. Note that FIGS. 3 and 4 do not illustrate a part of an insulator for the sake of descriptive convenience.

The semiconductor device 1 includes wirings 40, 41, 42, 43, 50, 51, 52, 53, and 54, vias 60, 61, 62, 63, 64, 65, and 66, and a sealing member 70. The MOSFET 20A includes electrodes 21A, 22A, and 23A. The MOSFET 20B includes electrodes 21B, 22B, and 23B.

The photocoupler 10 is provided above the substrate 5. The photocoupler 10 is sealed by the sealing member 70 that covers the upper portion of the substrate 5. The sealing member 70 may contain, for example, a non-translucent material.

The MOSFETs 20A and 20B are aligned with the photocoupler 10 in the Y direction. The MOSFETs 20A and 20B are arranged in the X direction in the substrate 5. As described above, the MOSFETs 20A and 20B are incorporated in the substrate 5. That is, the MOSFETs 20A and 20B are arranged at positions different from that of the photocoupler 10 in the Z direction, and thus they do not physically interfere with each other. Therefore, each of the MOSFETs 20A and 20B is arranged at a position overlapping the photocoupler 10 when viewed in the Y direction. With this arrangement, the interval in the X direction between the MOSFETs 20A and 20B is shorter than in a case where the MOSFETs 20A and 20B are arranged at positions not overlapping the photocoupler 10 when viewed in the Y direction. That is, the interval in the X direction between the MOSFETs 20A and 20B is shorter than the length in the X direction of the photocoupler 10.

The electrodes 21A and 22A are provided on the upper surface of the MOSFET 20A. For example, the electrode 22A is aligned with the electrode 21A in the Y direction to be located closer to the photocoupler 10 than the electrode 21A. The electrode 23A is provided on the lower surface of the MOSFET 20A. The electrode 21A serves as a source electrode. The electrode 22A serves as a gate electrode. The electrode 23A serves as a drain electrode.

The electrodes 21B and 22B are provided on the upper surface of the MOSFET 20B. For example, the electrode 22B is aligned with the electrode 21B in the Y direction to be located closer to the photocoupler 10 than the electrode 21B. The electrode 23B is provided on the lower surface of the MOSFET 20B. The electrode 21B serves as a source electrode. The electrode 22B serves as a gate electrode. The electrode 23B serves as a drain electrode.

The electrodes 31, 32, 33, and 34 are provided apart from each other on the lower surface of the substrate 5. The electrodes 31 and 32 are arranged in the X direction. The electrodes 33 and 34 are arranged in the X direction. The electrode 33 is provided at a position overlapping the MOSFET 20A when looking down at the semiconductor device 1. The electrode 34 is provided at a position overlapping the MOSFET 20B when looking down at the semiconductor device 1. The electrode 31 is located closer to the photocoupler 10 than the electrode 33, and is aligned with the electrode 33 in the Y direction. The electrode 32 is located closer to the photocoupler 10 than the electrode 34, and is aligned with the electrode 34 in the Y direction.

The wirings 40, 41, 42, and 43 are conductors provided apart from each other on the upper surface of the substrate 5. The wiring 40 has, for example, a T-shape. The wiring 40 includes a portion overlapping the photocoupler 10 and a portion not overlapping the photocoupler 10 when looking down at the semiconductor device 1. The portion, not overlapping the photocoupler 10, of the wiring 40 includes a portion 401 aligned with the photocoupler 10 in the Y direction, and two portions 402 and 403 sandwiching the photocoupler 10 in the X direction. The upper surface of the portion 401 of the wiring 40 contacts the terminal 16. The portions 402 and 403 of the wiring 40 are electrically connected to the terminal 16 via the portion 401. The wiring 41 has, for example, a rectangular shape. The upper surface of the wiring 41 contacts the terminal 15. The wiring 42 has, for example, a rectangular shape. The upper surface of the wiring 42 contacts the terminal 13. The wiring 43 has, for example, a rectangular shape. The upper surface of the wiring 43 contacts the terminal 14.

The wirings 50, 51, 52, 53, and 54 are conductors provided apart from each other in the substrate 5. The wiring 50 has, for example, a rectangular shape extending in the X direction. The wiring 50 contacts the upper surface of the electrode 21A of the MOSFET 20A and the upper surface of the electrode 21B of the MOSFET 20B. The wiring 51 has, for example, a rectangular shape extending in the Y direction. The wiring 51 contacts the upper surface of the electrode 22A of the MOSFET 20A. The wiring 52 has, for example, a rectangular shape extending in the Y direction. The wiring 52 contacts the upper surface of the electrode 22B of the MOSFET 20B. The wiring 53 contacts the lower surface of the electrode 23A of the MOSFET 20A. The wiring 54 contacts the lower surface of the electrode 23B of the MOSFET 20B.

The vias 60, 61, 62, 63, 64, 65, and 66 are conductors separated from each other in the substrate 5 and extending in the Z direction. The via 60 connects the lower surface of the wiring 41 and the upper surface of the wiring 50. The via 61 connects the lower surface of the portion 402 of the wiring 40 and the upper surface of the wiring 51. The via 62 connects the lower surface of the portion 403 of the wiring 40 and the upper surface of the wiring 52. The via 63 connects the lower surface of the wiring 53 and the upper surface of the electrode 33. The via 64 connects the lower surface of the wiring 54 and the upper surface of the electrode 34. The via 65 connects the lower surface of the wiring 42 and the upper surface of the electrode 31. The via 66 connects the lower surface of the wiring 43 and the upper surface of the electrode 32. Each of the vias 60, 61, 62, 63, 64, 65, and 66 may be formed by a plurality of vias.

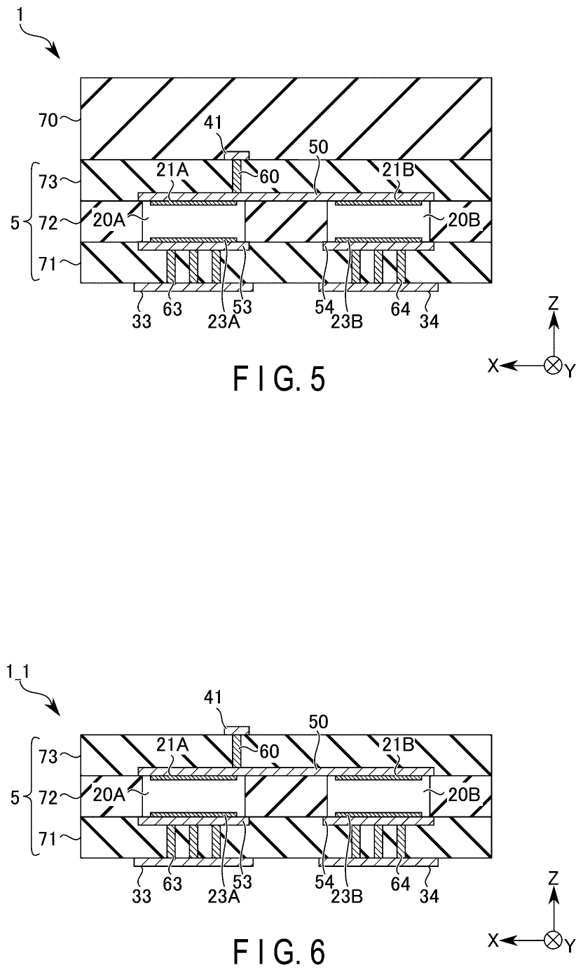

The sectional structure of the semiconductor device 1 will be described next with reference to FIG. 5. FIG. 5 is a sectional view taken along a line V - V in FIGS. 3 and 4 and showing an example of the sectional structure of the semiconductor device according to the first embodiment.

As shown in FIG. 5, the semiconductor device 1 further includes insulator layers 71, 72, and 73. The insulator layers 71, 72, and 73 are base materials forming the substrate 5. The insulator layer 72 is provided on the upper surface of the insulator layer 71. The insulator layer 73 is provided on the upper surface of the insulator 72. The sealing member 70 is provided on the upper surface of the insulator layer 73.

The lower surface of the insulator layer 71 corresponds to the lower surface of the substrate 5. That is, the electrodes 31, 32, 33, and 34 are provided on the lower surface of the insulator layer 71. The wirings 53 and 54 are provided on the upper surface of the insulator layer 71. Then, in the insulator layer 71, the vias 63 and 64, a portion of the via 65, and a portion of the via 66 extend in the Z direction.

The MOSFETs 20A and 20B are provided in the same layer as the insulator layer 72. The example shown in FIG. 5 indicates a case where the lower surfaces of the MOSFETs 20A and 20B are aligned with the lower surface of the insulator layer 72 and the upper surfaces of the MOSFETs 20A and 20B are aligned with the upper surface of the insulator layer 72. In the insulator layer 72, a portion of the via 65 and a portion of the via 66 extend in the Z direction.

The upper surface of the insulator layer 73 corresponds to the upper surface of the substrate 5. That is, the wirings 40, 41, 42, and 43 are provided on the upper surface of the insulator layer 73. The wirings 50, 51, and 52 are provided on the lower surface of the insulator layer 73. Then, in the insulator layer 73, the vias 60, 61, 62, a portion of the via 65, and a portion of the via 66 extend in the Z direction.

With the above arrangement, the substrate 5 functions as a component incorporating multilayered wiring board that incorporates the MOSFETs 20A and 20B and includes wirings in four layers including the lower surface of the insulator layer 71, the boundary between the insulator layers 71 and 72, the boundary between the insulator layers 72 and 73, and the upper surface of the insulator layer 73.

Note that the first embodiment has explained a case where the vias 65 and 66 electrically connect the wirings on the lower surface of the insulator layer 71 and the wirings on the upper surface of the insulator layer 73 without intervention of the wirings provided at the boundary between the insulator layers 71 and 72 and the boundary between the insulator layers 72 and 73, but the present invention is not limited to this. For example, the vias 65 and 66 may be configured to electrically connect the wirings on the lower surface of the insulator layer 71 and the wirings on the upper surface of the insulator layer 73 via the wirings provided at the boundary between the insulator layers 71 and 72 and the boundary between the insulator layers 72 and 73.

According to the first embodiment, the substrate 5 incorporates the MOSFETs 20A and 20B and the wiring 50. The wiring 50 extends in the X direction in the substrate 5, and contacts each of the electrode 21A of the MOSFET 20A and the electrode 21B of the MOSFET 20B. The photocoupler 10 is provided on the upper surface of the substrate 5. The terminal 15 of the photocoupler 10 is electrically connected to the electrode 21A of the MOSFET 20A and the electrode 21B of the MOSFET 20B via the wiring 50. The terminal 16 of the photocoupler 10 is electrically connected to the electrode 22A of the MOSFET 20A and the electrode 22B of the MOSFET 20B. Thus, the semiconductor device 1 can be configured to electrically connect the terminal 15 of the photocoupler 10 to the electrode 21A of the MOSFET 20A and the electrode 21B of the MOSFET 20B without using a relatively high-resistance wiring such as a bonding wire. It is thus possible to suppress an increase in ON resistance of the MOSFETs 20A and 20B. Therefore, it is possible to suppress an increase in heat generation amount of the semiconductor device 1.

In addition, since the MOSFETs 20A and 20B are arranged at positions different from that of the photocoupler 10 in the Z direction, they do not physically interfere with each other. Thus, the interval in the X direction between the MOSFETs 20A and 20B can be made shorter than the length in the X direction of the photocoupler 10. Therefore, the length in the X direction of the semiconductor device 1 can be made shorter than in a case where the MOSFETs 20A and 20B are arranged on the upper surface of the substrate 5. The size of the semiconductor device 1 can thus be reduced more.

### Modification of First Embodiment

Note that various modifications can be applied to the above-described first embodiment.

The above first embodiment has explained a case where the photocoupler 10 and the wirings 40, 41, 42, and 43 provided on the upper surface of the substrate 5 are sealed by the sealing member 70 but the present invention is not limited to this. For example, the photocoupler 10 and the wirings 40, 41, 42, and 43 provided on the upper surface of the substrate 5 need not be sealed by the sealing member 70.

FIG. 6 is a sectional view showing an example of the sectional structure of the semiconductor device according to a modification of the first embodiment. FIG. 6 corresponds to FIG. 5 in the first embodiment.

As shown in FIG. 6, a semiconductor device 1_1 includes no sealing member 70. That is, the upper surface of the insulator layer 73 is exposed to the outside without being sealed by the sealing member 70.

According to the modification of the first embodiment, similar to the semiconductor device 1 of the first embodiment, the semiconductor device 1_1 can be configured to electrically connect the terminal 15 of the photocoupler 10 to the electrode 21A of the MOSFET 20A and the electrode 21B of the MOSFET 20B without using a relatively high-resistance wiring such as a bonding wire. It is thus possible to suppress an increase in ON resistance of the MOSFETs 20A and 20B. Therefore, it is possible to suppress an increase in heat generation amount of the semiconductor device 1_1.

In addition, since the MOSFETs 20A and 20B are arranged at positions different from that of the photocoupler 10 in the Z direction, they do not physically interfere with each other. The size of the semiconductor device 1_1 can thus be reduced more.

### 2. Second Embodiment

A semiconductor device according to the second embodiment will be described next. Components different from those in the first embodiment will mainly be described below. A description of the same components as in the first embodiment will appropriately be omitted.

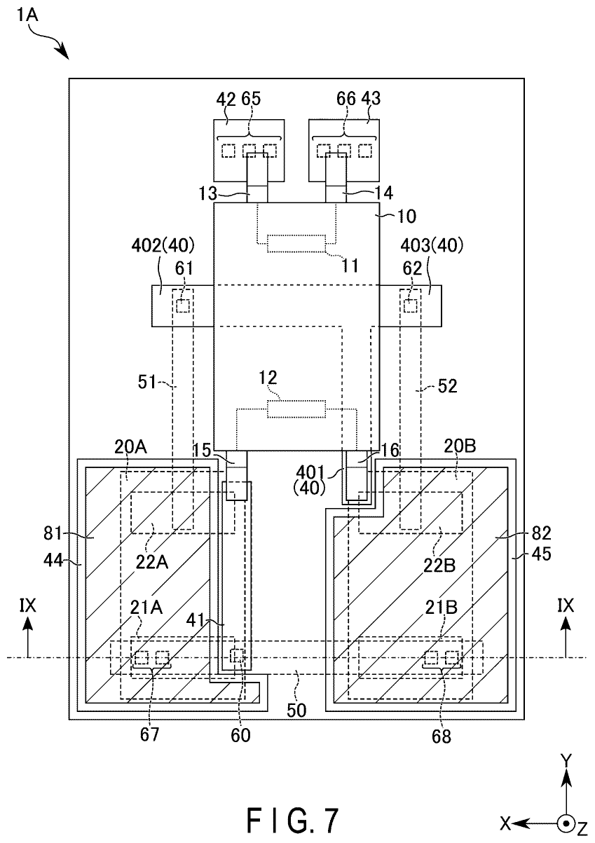

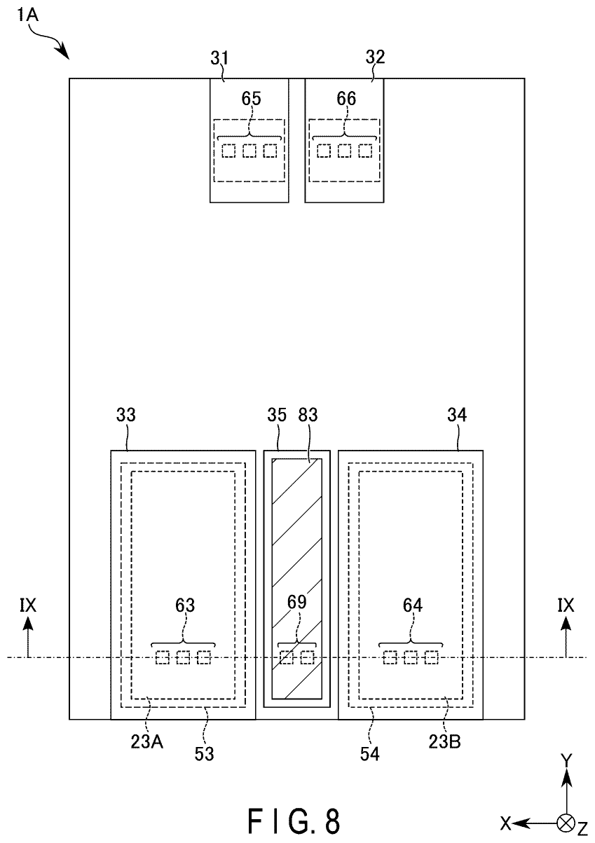

FIG. 7 is a plan view showing an example of the planar layout of the upper surface of the semiconductor device according to the second embodiment. FIG. 8 is a plan view showing an example of the planar layout of the lower surface of the semiconductor device according to the second embodiment. FIGS. 7 and 8 correspond to FIGS. 3 and 4 in the first embodiment, respectively.

A semiconductor device 1A further includes wirings 35, 44, and 45, vias 67, 68, and 69, and cooling devices 81, 82, and 83.

The wirings 44 and 45 are conductors provided apart from each other on the upper surface of a substrate 5. The wiring 44 is provided to overlap a portion excluding a first region of a MOSFET 20A, which does not interfere with a wiring 41 and a terminal 15, when looking down at the semiconductor device 1A. The wiring 45 is provided to overlap a portion excluding a second region of a MOSFET 20B, which does not interfere with a wiring 40 and a terminal 16, when looking down at the semiconductor device 1A.

The wiring 35 is a conductor provided on the lower surface of the substrate 5. The wiring 35 is provided between electrodes 33 and 34 to be separated from the electrodes 33 and 34.

The via 67 connects the upper surface of a wiring 50 and the lower surface of the wiring 44. The via 68 connects the upper surface of the wiring 50 and the lower surface of the wiring 45. The via 69 connects the upper surface of the wiring 35 and the lower surface of the wiring 50. That is, the wiring 35, 44, and 45 are at the same potential as the wiring 50. Each of the vias 67, 68, and 69 may be formed by a plurality of vias.

The cooling devices 81, 82, and 83 are, for example, heat sinks. The cooling device 81 is provided on the upper surface of the wiring 44. The cooling device 82 is provided on the upper surface of the wiring 45. The cooling device 83 is provided on the lower surface of the wiring 35. The cooling devices 81 and 82 are sealed by a sealing member 70 together with a photocoupler 10.

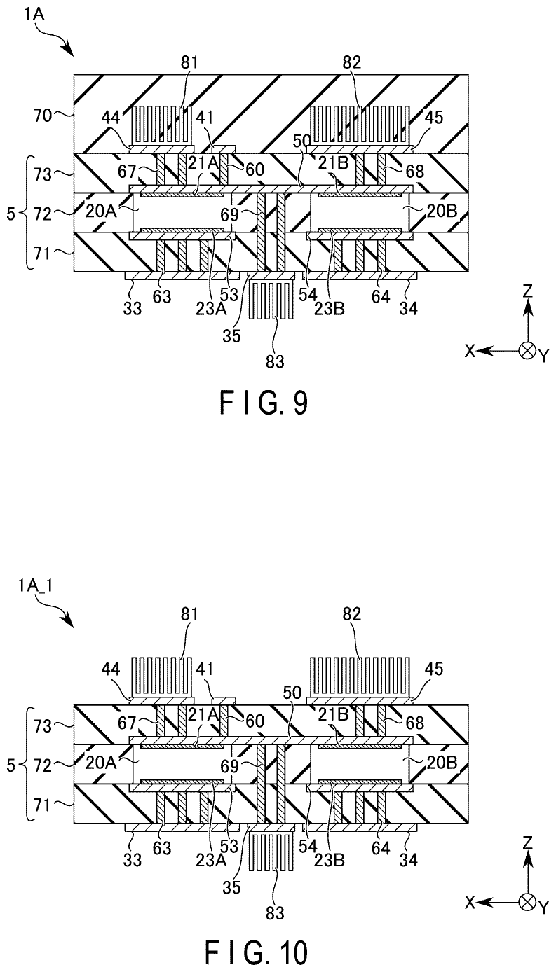

The sectional structure of the semiconductor device 1A will be described next with reference to FIG. 9. FIG. 9 is a sectional view taken along a line IX-IX in FIGS. 7 and 8 and showing an example of the sectional structure of the semiconductor device according to the second embodiment. FIG. 9 corresponds to FIG. 5 in the first embodiment.

As shown in FIG. 9, the wiring 35 is provided between the electrodes 33 and 34 on the lower surface of an insulator layer 71. Then, the vias 69 extend in the Z direction in the insulator layer 71 and an insulator layer 72.

The wirings 44 and 45 are provided on the upper surface of an insulator layer 73. Then, the vias 67 and 68 extend in the Z direction in the insulator layer 73.

With the above arrangement, the semiconductor device 1A can dissipate heat generated by the MOSFETs 20A and 20B to the cooling device 81 via the vias 67 and the wiring 44, to the cooling device 82 via the vias 68 and the wiring 45, and to the cooling device 83 via the vias 69 and the wiring 35. This can further improve the heat dissipation characteristic of the semiconductor device 1A.

### Modifications of Second Embodiment

Note that various modifications can be applied to the above-described second embodiment.

The above second embodiment has explained a case where the wirings 40, 41, 42, 43, 44, and 45 provided on the upper surface of the substrate 5, the cooling devices 81 and 82, and the photocoupler 10 are sealed by the sealing member 70, but the present invention is not limited to this. For example, the wirings 40, 41, 42, 43, 44, and 45 provided on the upper surface of the substrate 5, the cooling devices 81 and 82, and the photocoupler 10 need not be sealed by the sealing member 70.

FIG. 10 is a sectional view showing an example of the sectional structure of a semiconductor device according to the first modification of the second embodiment. FIG. 10 corresponds to FIG. 9 in the second embodiment.

As shown in FIG. 10, a semiconductor device 1A_1 includes no sealing member 70. That is, the upper surface of the insulator layer 73 is exposed to the outside without being sealed by the sealing member 70. With the above arrangement, the semiconductor device 1A_1 can dissipate heat generated by the MOSFETs 20A and 20B from the cooling devices 81, 82, and 83 to the outside without intervention of the sealing member 70. This can further improve the heat dissipation characteristic of the semiconductor device 1A_1.

According to the first modification of the second embodiment, similar to the semiconductor device 1A of the second embodiment, the semiconductor device 1A_1 can be configured to electrically connect the terminal 15 of the photocoupler 10 to the electrode 21A of the MOSFET 20A and the electrode 21B of the MOSFET 20B without using a relatively high-resistance wiring such as a bonding wire. It is thus possible to suppress an increase in ON resistance of the MOSFETs 20A and 20B. Therefore, it is possible to suppress an increase in heat generation amount of the semiconductor device 1A_1.

Since the MOSFETs 20A and 20B are arranged at positions different from that of the photocoupler 10 in the Z direction, they do not physically interfere with each other. Therefore, the size of the semiconductor device 1A_1 can be reduced more.

The second embodiment and the first modification of the second embodiment have explained a case where the two cooling devices 81 and 82 are provided in correspondence with the two MOSFETs 20A and 20B, but the present invention is not limited to this. One cooling device may be provided on the upper surface of the substrate 5 to cover a region that overlaps both the two MOSFETs 20A and 20B.

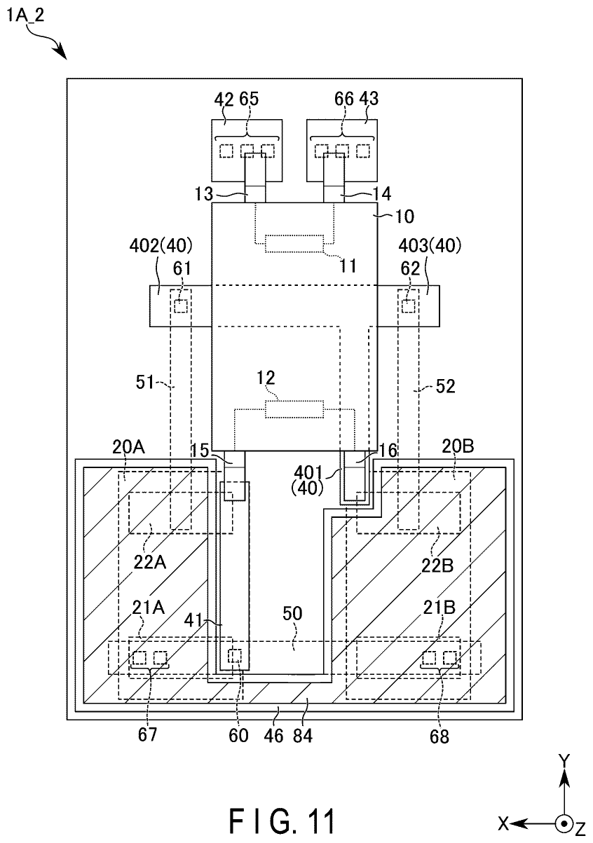

FIG. 11 is a plan view showing an example of the planar layout of the upper surface of a semiconductor device according to the second modification of the second embodiment. FIG. 11 corresponds to FIG. 7 in the second embodiment.

As shown in FIG. 11, a semiconductor device 1A_2 includes a wiring 46 instead of the wirings 44 and 45. The semiconductor device 1A_2 also includes a cooling device 84 instead of the cooling devices 81 and 82.

The wiring 46 is provided over a first region of the MOSFET 20A, which does not interfere with the wiring 41 and the terminal 15, a second region of the MOSFET 20B, which does not interfere with the wiring 40 and the terminal 16, and a third region which connects the first region and the second region, when looking down at the semiconductor device 1A_2. The example shown in FIG. 11 indicates a case where the third region extends in the X direction on the opposite side of the photocoupler 10 with respect to the wiring 41 on the upper surface of the substrate 5, and connects the first region and the second region.

The cooling device 84 is, for example, a heat sink. The cooling device 84 is provided on the upper surface of the wiring 46. The cooling device 84 is sealed by the sealing member 70 together with the photocoupler 10. As indicated in the first modification of the second embodiment, the cooling device 84 may be exposed to the upper surface of the substrate 5 together with the photocoupler 10.

According to the second modification of the second embodiment, the area of the cooling device can be widened, as compared to a case where the cooling devices are arranged above the MOSFETs 20A and 20B, respectively. This can further improve the heat dissipation effect.

The second modification of the second embodiment has explained a case where the third region of the wiring 46 is provided to wrap around the wiring 41, but the present invention is not limited to this. The photocoupler 10 may be arranged while being further shifted in the Y direction with respect to the MOSFETs 20A and 20B so that the third region of the wiring 46 is provided not to wrap around the wiring 41.

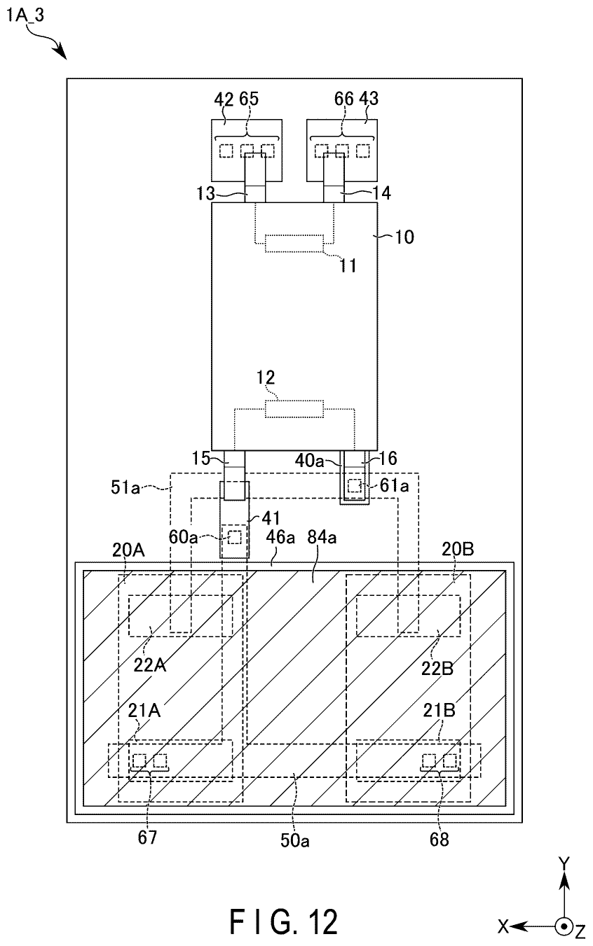

FIG. 12 is a plan view showing an example of the planar layout of the upper surface of a semiconductor device according to the third modification of the second embodiment. FIG. 12 corresponds to FIG. 11 in the second modification of the second embodiment.

As shown in FIG. 12, a semiconductor device 1A_3 includes wirings 40a, 46a, 50a, and 51a instead of the wirings 40, 46, 50, 51, and 52. The semiconductor device 1A_3 includes vias 60a and 61a instead of the vias 60, 61, and 62. The semiconductor device 1A_3 includes a cooling device 84a instead of the cooling device 84.

The photocoupler 10 is arranged while being shifted in the Y direction so the terminals 15 and 16 do not overlap the MOSFETs 20A and 20B when looking down at the semiconductor device 1A_3.

The wiring 40a is a conductor provided on the upper surface of the substrate 5. More specifically, for example, the wiring 40a corresponds to the portion 401 of the wiring 40 in the second modification of the second embodiment. That is, the terminal 16 contacts the upper surface of the wiring 40a.

The wirings 50a and 51a are conductors provided in the substrate 5. The wiring 50a has, for example, T-shape. A portion extending in the X direction of the wiring 50a corresponds to the wiring 50 in the second modification of the second embodiment. A portion extending in the Y direction of the wiring 50a includes a portion overlapping the wiring 41 when looking down at the semiconductor device 1A_3. The portion extending in the Y direction of the wiring 50a and the wiring 41 are connected by the via 60a. The wiring 51a includes a portion extending in the X direction, a portion that is connected to one end of the portion extending in the X direction and extends in the Y direction, and a portion that is connected to the other end of the portion extending in the X direction and extends in the Y direction. The portion extending in the X direction of the wiring 51a includes a portion that overlaps the wiring 40a when looking down at the semiconductor device 1A_3. The portion extending in the X direction of the wiring 51a and the wiring 40a are connected by the via 61a. The lower surface of the portion of the wiring 51a, which is connected to one end of the portion extending in the X direction and extends in the Y direction, contacts the upper surface of the electrode 22A of the MOSFET 20A. The lower surface of the portion of the wiring 51a, which is connected to the other end of the portion extending in the X direction and extends in the Y direction, contacts the upper surface of the electrode 22B of the MOSFET 20B.

The wiring 46a is provided over a first region that does not interfere with the MOSFET 20A, a second region that does not interfere with the MOSFET 20B, and a third region that connects the first region and the second region, when looking down at the semiconductor device 1A_3. In the example shown in FIG. 12, the third region connects the portion between the MOSFETs 20A and 20B on the upper surface of the substrate 5.

The cooling device 84a is, for example, a heat sink. The cooling device 84a is provided on the upper surface of the wiring 46a.

According to the third modification of the second embodiment, the area of the cooling device can further be widened. This can further improve the heat dissipation characteristic of heat generated by the MOSFETs 20A and 20B.

The third modification of the second embodiment has explained a case where the third region of the wiring 46 is provided in the portion between the MOSFETs 20A and 20B, but the present invention is not limited to this. The third region of the wiring 46 may be provided in the entire region of the upper surface of the substrate 5 except for a region where the photocoupler 10 is provided.

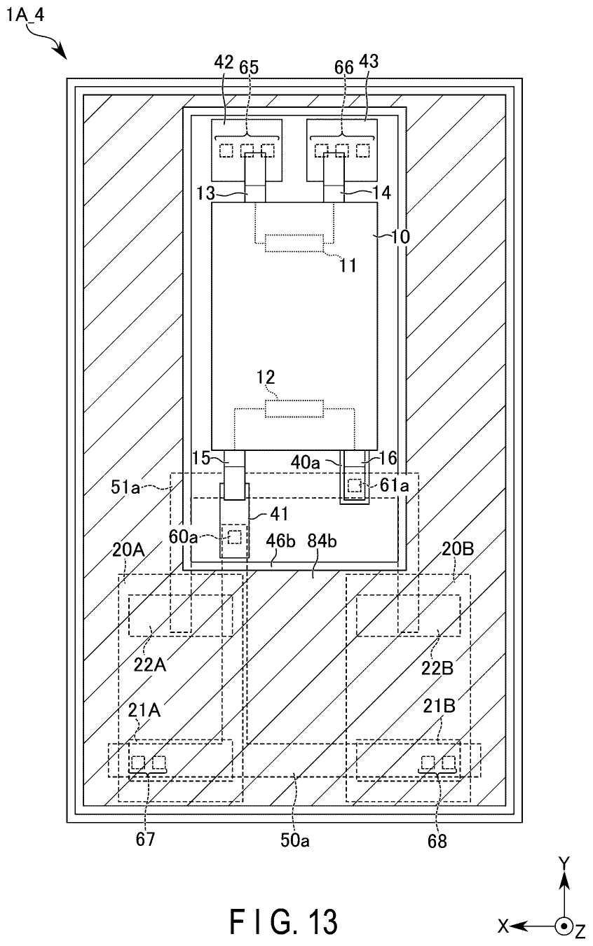

FIG. 13 is a plan view showing an example of the planar layout of the upper surface of a semiconductor device according to the fourth modification of the second embodiment. FIG. 13 corresponds to FIG. 12 in the third modification of the second embodiment.

As shown in FIG. 13, a semiconductor device 1A_4 includes a wiring 46b instead of the wiring 46a. The semiconductor device 1A_4 includes a cooling device 84b instead of the cooling device 84a.

The wiring 46b is provided over a region that does not interfere with the photocoupler 10 on the upper surface of the substrate 5 when looking down at the semiconductor device 1A_4. In the example shown in FIG. 13, the wiring 46b is provided over the entire region of the upper surface of the substrate 5 to surround the photocoupler 10.

The cooling device 84b is, for example, a heat sink. The cooling device 84b is provided on the upper surface of the wiring 46b.

According to the fourth modification of the second embodiment, the area of the cooling device can further be widened. This can further increase the area of the cooling device. Thus, it is possible to further improve the heat dissipation characteristic of heat generated by the MOSFETs 20A and 20B.

### 3. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a first transistor and a second transistor provided in the substrate;
a first wiring provided in the substrate and contacting each of a source electrode of the first transistor and a source electrode of the second transistor; and
a photocoupler provided on an upper surface of the substrate and configured to control states of the first transistor and the second transistor.

2. The device according to claim 1, wherein
the photocoupler includes
a first terminal electrically connected to the source electrode of the first transistor and the source electrode of the second transistor via the first wiring, and
a second terminal electrically connected to a gate electrode of the first transistor and a gate electrode of the second transistor.

3. The device according to claim 1, wherein
the first transistor and the second transistor are arranged in a first direction, and
an interval in the first direction between the first transistor and the second transistor is shorter than a length in the first direction of the photocoupler.

4. The device according to claim 1, further comprising:
a second wiring provided on the upper surface of the substrate, and at a position overlapping the first transistor;
a third wiring provided on the upper surface of the substrate, and at a position overlapping the second transistor;
a first via provided in the substrate and configured to connect an upper surface of the first wiring and a lower surface of the second wiring; and
a second via provided in the substrate and configured to connect the upper surface of the first wiring and a lower surface of the third wiring.

5. The device according to claim 4, further comprising:
a first cooling device provided on an upper surface of the second wiring; and
a second cooling device provided on an upper surface of the third wiring.

6. The device according to claim 5, further comprising:
a fourth wiring provided on the upper surface of the substrate, and continuously connecting the second wiring and the third wiring; and
a third cooling device provided on an upper surface of the fourth wiring, and continuously connecting the first cooling device and the second cooling device.

7. The device according to claim 6, wherein
the photocoupler includes a first terminal electrically connected to the source electrode of the first transistor and the source electrode of the second transistor via the first wiring, and
the semiconductor device further includes
a fifth wiring provided on the upper surface of the substrate and connected to the first terminal, and
a third via configured to connect the first wiring and the fourth wiring.

8. The device according to claim 7, wherein
each of the first terminal and the fifth wiring includes a portion sandwiched by the second wiring and the third wiring.

9. The device according to claim 7, wherein
each of the first terminal and the fifth wiring is located closer to the photocoupler than each of the second wiring and the third wiring.

10. The device according to claim 7, wherein
the fourth wiring and the third cooling device are provided to surround the photocoupler.

11. The device according to claim 1, further comprising:
a sixth wiring provided on a lower surface of the substrate; and
a fourth via provided in the substrate and configured to connect a lower surface of the first wiring and an upper surface of the sixth wiring.

12. The device according to claim 11, further comprising:
a fourth cooling device provided on a lower surface of the sixth wiring.

13. The device according to claim 1, further comprising:
a sealing member configured to cover the photocoupler.

14. The device according to claim 1, wherein
the photocoupler is a package including a light-emitting element and a light-receiving element.
